(19) United States
(12) Patent Application Publication
(10) Pub. No.: US 2024/0355773 A1
(43) Pub. Date: Oct. 24, 2024

(54) SEMICONDUCTOR DEVICE AND A METHOD FOR FORMING A SEMICONDUCTOR DEVICE

(71) Applicant: STATS ChipPAC Pte. Ltd., Singapore (SG)

(72) Inventors: KyungEun KIM, Incheon (KR); HaengCheol CHOI, Kyeonggi-do (KR); YoungJin WOO, Gyeonggi-do (KR); HyunKyum KIM, Gyeonggi-do (KR)

(21) Appl. No.: 18/638,733

(22) Filed: Apr. 18, 2024

(30) Foreign Application Priority Data
Apr. 19, 2023 (CN) 202310423188.X

(51) Int. Cl. H01L 23/00; H01L 25/065

(52) U.S. Cl. CPC H01L 24/40; H01L 24/08; H01L 24/32; H01L 24/35; H01L 24/37; H01L 24/73; H01L 25/0657; H01L 24/16; H01L 24/48; H01L 2224/08225; H01L 2224/16225; H01L 2224/32145; H01L 2224/35985; H01L 2224/37; H01L 2224/40225; H01L 2224/48227; H01L 2224/73253; H01L 2224/73255; H01L 2224/73257; H01L 2224/73263; H01L 2224/73265; H01L 2924/151

(57) ABSTRACT

A semiconductor device comprises: a substrate having a set of conductive patterns; a semiconductor die mounted on the substrate, wherein the semiconductor die has on its top surface a set of bonding pads; and a conductive bar assembly for electrically connecting the set of conductive patterns of the substrate with the set of bonding pads of the semiconductor die, wherein the conductive bar assembly comprises: an insulating body; and a set of conductive bars extending within the insulating body, wherein the set of conductive bars have a set of first ends exposed from a first surface of the insulating body to be electrically connected to the set of conductive patterns of the substrate and a set of second ends exposed from a second surface of the insulating body to be electrically connected to the set of bonding pads of the semiconductor die.

### TECHNICAL FIELD

The present application generally relates to semiconductor technology, and more particularly, to a semiconductor device and a method for forming a semiconductor device.

### BACKGROUND OF THE INVENTION

In recent years, die mounting, also known as chip-on-board, has become increasingly popular for reducing the footprint of electronics in space-restricted devices. Semiconductor dice are directly mounted on a substrate on a printed circuit board (PCB) using die-attach techniques and electronically connected to the PCB by wire bonding or flip-chip attaching.

FIGS. 1A and 1B illustrate a conventional semiconductor device 10 with bonding wires. As illustrated in FIGS. 1A and 1B, a substrate 12 can be used to attach various electronic components thereon, such as a flip-chip (FC) type semiconductor die 14 and a wire bonding (WB) type semiconductor die 16. The FC type die 14 is mounted to the substrate 12 via solder bumps 18, and the WB type die 16 is attached onto the FC type die 14 via adhesive (not shown). Bonding pads 20, which are topmost of the WB type die 16 are further electrically connected to conductive pads 22 on the substrate 12 via bonding wires 24. However, in order to perform open-short (OS) test to the semiconductor die 16, some plating traces 26 and ports 28 are desired to extend the conductive pads 22 out of the substrate 12. Such plating traces 26 need etch back processing, which increases the complexity of the entire process.

Therefore, a need exists for an improved semiconductor device and a method for forming such semiconductor device.

### SUMMARY OF THE INVENTION

An objective of the present application is to provide a semiconductor device with a simplified manufacturing process.

According to an aspect of the present application, a semiconductor device is provided, which comprises: a substrate having a set of conductive patterns; a semiconductor die mounted on the substrate, wherein the semiconductor die has on its top surface a set of bonding pads; and a conductive bar assembly for electrically connecting the set of conductive patterns of the substrate with the set of bonding pads of the semiconductor die, wherein the conductive bar assembly comprises: an insulating body; and a set of conductive bars extending within the insulating body, wherein the set of conductive bars have a set of first ends exposed from a first surface of the insulating body to be electrically connected to the set of conductive patterns of the substrate and a set of second ends exposed from a second surface of the insulating body to be electrically connected to the set of bonding pads of the semiconductor die.

According to another aspect of the present application, a method for forming a semiconductor device is provided. The method comprises: providing a substrate having a set of conductive patterns; mounting a semiconductor die on the substrate, wherein the semiconductor die has on its top surface a set of bonding pads; providing a conductive bar assembly comprising an insulating body and a set of conductive bars extending within the insulating body, wherein the set of conductive bars have a set of first ends exposed from a first surface of the insulating body and a set of second ends exposed from a second surface of the insulating body; and attaching the set of first ends of the set of conductive bars to the set of conductive patterns of the substrate and the set of second ends of the set of conductive bars to the set of bonding pads of the semiconductor die to form the semiconductor device.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A and 1B illustrate a conventional semiconductor device 10 with bonding wires.

FIGS. 2A and 2B illustrate a semiconductor device 200 according to an embodiment of the present application. FIG. 2A is a top view of the semiconductor device 200, and FIG. 2B is a cross sectional view of the semiconductor device 200 shown in FIG. 2A.

FIG. 2C illustrates a perspective view of two conductive bar assemblies 230 mounted on the substrate 212 shown in FIGS. 2A and 2B.

FIG. 3 illustrates an explosive view of an exemplary conductive bar assembly according to an embodiment of the present application.

FIG. 4 illustrates a semiconductor device 400 according to an embodiment of the present application.

FIG. 5 illustrates a semiconductor device 500 according to an embodiment of the present application.

FIG. 6 illustrates a method 600 for forming a semiconductor device according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

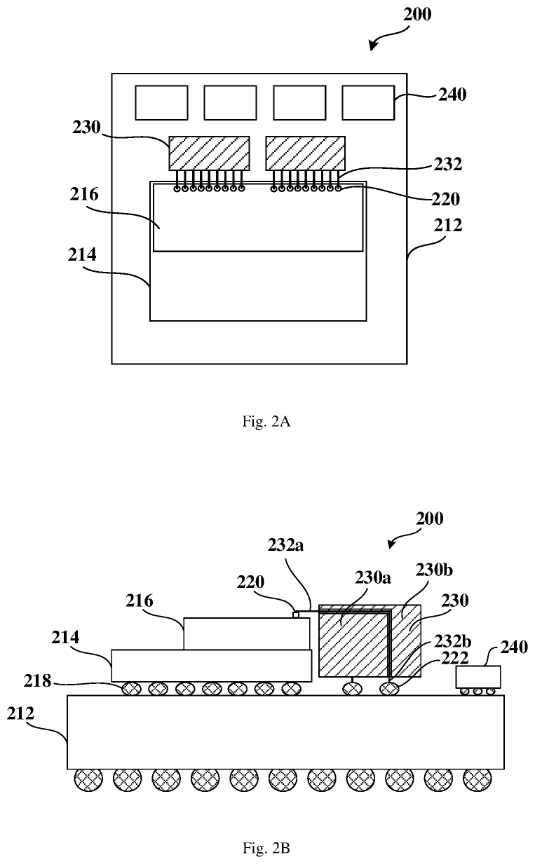

FIGS. 2A and 2B illustrate a semiconductor device 200 according to an embodiment of the present application. FIG. 2A is a top view of the semiconductor device 200, and FIG. 2B is a cross sectional view of the semiconductor device 200 shown in FIG. 2A.

As shown in FIGS. 2A and 2B, the semiconductor device 200 includes a substrate 212, which can provide support and connectivity for electrical components and devices mounted thereon. By way of example, the substrate 212 can include a printed circuit board (PCB), a carrier substrate, a semiconductor substrate with electrical interconnections, or a ceramic substrate. However, the substrate 212 is not to be limited to these examples. In some other examples, the substrate 212 may include a laminate interposer, a strip interposer, a leadframe, or other suitable substrates. The substrate 212 may include any structure on or in which an integrated circuit system can be fabricated. For example, the substrate 212 may include one or more insulating or passivation layers, one or more conductive vias formed through the insulating layers, and one or more conductive layers formed over or between the insulating layers.

The substrate 212 may include a plurality of interconnection structures. The interconnection structures can provide connectivity for electrical components mounted on the substrate 212. The interconnection structures may include one or more of Cu, Al, Sn, Ni, Au, Ag, or any other suitable electrically conductive materials. In some examples, the interconnection structures may include redistribution structures. The redistribution structures may include one or more dielectric layers and one or more conductive layers between and through the dielectric layers. The conductive layers may define pads, traces and plugs through which electrical signals or voltages can be distributed horizontally and vertically across the redistribution structures.

As a part of the interconnection structures, the interconnection structures can include conductive patterns on a top surface of the substrate 212, for mounting electronic components, chips, etc. In some embodiments, the interconnection structures may further include conductive patterns on a bottom surface of the substrate 212, for mounting the semiconductor device 200 to another base plate or device.

In the embodiment shown in FIGS. 2A and 2B, two semiconductor dice 214 and 216 may be stacked together and attached on the substrate 212. In some embodiments, the semiconductor die 214 may be a flip-chip type semiconductor die, which can be mounted onto a set of conductive patterns on the top surface of the substrate via a set of conductive pillars or solder bumps 218. Furthermore, the upper semiconductor die 216 may be attached onto the top surface of the lower semiconductor die 214 via adhesive, to avoid occupying space of the substrate 212. In some embodiments, the upper semiconductor die 216 may be a wire bonding type semiconductor die, which has on its top surface a set of bonding pads 220 for interconnection purpose. In some embodiments, the two semiconductor dice 214 and 216 are unpackaged raw semiconductor chips, and in some other embodiments, the two semiconductor dice 214 and 216 may be packaged semiconductor chips.

Other than the first set of conductive patterns which the semiconductor die 214 is connected to and covers, the interconnection structures of the substrate 212 may have a second set of conductive patterns for connecting the semiconductor die 216 with the substrate 212, and further with other components or devices mounted on the substrate 212. In particular, the second set of conductive patterns may be disposed besides the stack of semiconductor dice 214 and 216. A conductive bar assembly 230 may be used to electrically connect the second set of conductive patterns with the bonding pads 220 on top of the semiconductor die 216. In some embodiments, the conductive bar assembly 230 is a preformed piece, with a size, shape and layout of conductive bars that are compatible with the semiconductor die 216 and the second set of conductive patterns on the substrate 212. The conductive bar assembly 230 may be attached to the second set of conductive patterns via a set of conductive pillars or solder bumps 222, as shown in FIG. 2B. Similarly, the conductive bar assembly 230 may be attached to the bonding pads 220 on top of the semiconductor die 216 via solder bumps, for example.

In particular, the conductive bar assembly 230 may include an insulating body and a set of conductive bars 232 extending within the insulating body. The insulating body may be made of insulating material such as ceramics, plastics, resin, or any other suitable materials, which can provide support for the internal conductive bars and protect the conductive bars from the external environment and shock. The set of conductive bars 232 may have a set of first ends 232a exposed from a first surface of the insulating body, and a set of second ends 232b exposed from a second surface of the insulating body. The first surface and the second surface may be different surfaces, as illustrated in FIG. 2B. In some alternative embodiments, the first surface and the second surface may be the same surface when the insulating body takes a non-regular shape. In this way, the set of first ends 232a can be electrically connected to the set of bonding pads 220 of the semiconductor die 216, which are besides the conductive bar assembly 230; and the set of second ends 232b can be electrically connected to the second set of conductive patterns of the substrate, which are under the conductive bar assembly 230. In the embodiment shown in FIG. 2B, the insulating body includes a base 230a and a cover 230b, and the set of conductive bars 232 are disposed between the base 230a and the cover 230b. However, in some other embodiments, the insulating body may be of other structures. For example, the insulating body may be formed as a single piece, with an internal channel for accommodating and guiding the conductive bars 232 therein.

Some other electronic components or devices 240 such as board-to-board connector, resistors, capacitors or antennas may be mounted to the substrate 212. In some embodiments, an encapsulant layer may be further formed on the substrate 212, which may cover the semiconductor dice 214 and 216 and the conductive bar assembly 230, but may not cover the electronic components 240. Furthermore, a partial shielding layer may be further deposited on the encapsulant layer for shielding electromagnetic interference. It can be appreciated that any suitable processes for forming encapsulant layers and shielding layers may be performed to the semiconductor device 200.

FIG. 2C illustrates a perspective view of two conductive bar assemblies 230 mounted on the substrate 212 shown in FIGS. 2A and 2B.

As illustrated in FIG. 2C, each of the two conductive bar assemblies 230 is shaped as a cuboid, with a bottom surface facing towards the top surface of the substrate 212 and a lateral surface facing towards the two semiconductor dice 214 and 216. The set of first ends 232a in form of pins or fingers are exposed from the lateral surface, and are aligned with the set of bonding pads 220 on top of the second semiconductor die 216 in a vertical direction of the substrate 212. In this way, the set of first ends 232a can be easily connected to the set of bonding pads 220, for example, via solder bumps. In addition, the set of second ends 232b exposed from the bottom surface of the conductive bar assembly 230 may be connected to the conductive patterns 222 on the substrate 212, via solder bumps. It can be appreciated that the conductive bar assemblies 230 shown in FIG. 2C are exemplary only and are not limiting. For example, the insulating body of the conductive bar assemblies 230 may have a height slightly smaller than a combined height of the stacked semiconductor dice 214 and 216, and the set of first ends 232a may be exposed from the top surface of the insulating body and then extend horizontally along the top surface towards the bonding pads 220 on the semiconductor die 216. As such, the set of first ends 232a can also be easily connected to the bonding pads 220 without other complicated interconnect structures. In some alternative embodiments, the set of second ends 232b of the conductive bars 232 may be exposed from another lateral surface of the insulating body, slightly higher than the conductive patterns on the substrate 212 such that they can be attached to the conductive patterns easily without other complicated interconnect structures. In some embodiments, the conductive bar assembly 230 may be attached to the substrate 212 in a way similar as flip chip dices, i.e., using surface mounting attaching.

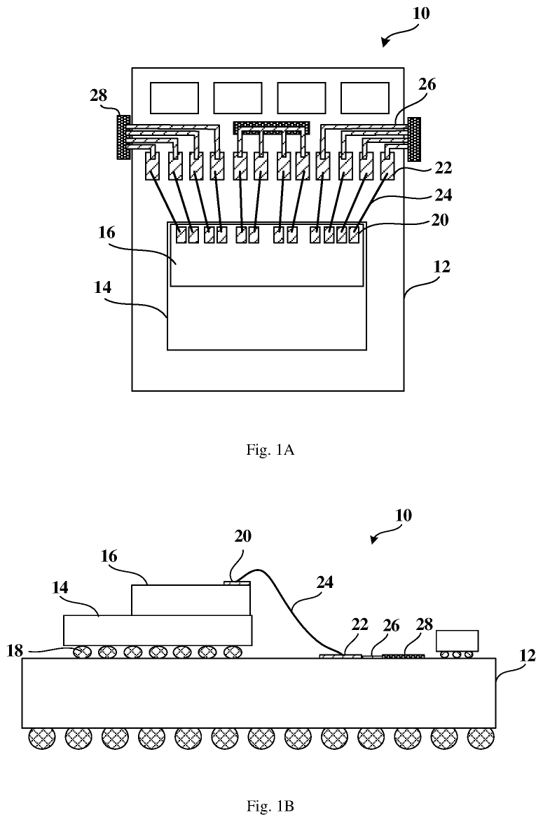

It can be seen that, compared with the conventional semiconductor device 10 shown in FIGS. 1A and 1B, the semiconductor device 200 shown in FIGS. 2A to 2C uses the conductive bar assembly to interconnect a wire bond type semiconductor die with the conductive patterns on the substrate, which is compact in structure and can resist significant shock from the external environment. Also, since the conductive bars have already been isolated from each other through the insulating material of the insulating body, no further molding process is desired, which however is required for the semiconductor device 10 shown in FIGS. 1A and 1B because bonding wires may be moved easily and thus wire short risk exists. Thus, the process to form the semiconductor device 200 can be simplified. In addition, the process can be further simplified because only a combination of an organic solderability preservatives (OSP) process and a solder on pad (SOP) process, or a combination of an electroless nickel electroless palladium immersion gold (ENEPIG) process and a SOP process is desired to form the various conductive structures on the substrate, which are easier to implement than the Ni/Au plating and etchback processes required by the conventional semiconductor devices.

Furthermore, as to the semiconductor device according to some embodiments of the present application, it can be either formed with a strip type structure and mounted onto a substrate strip, which may be subsequently singulated into multiple units of semiconductor devices, or formed with a unit type structure and directly mounted onto a singulated structure such as that shown in FIGS. 2A and 2B. In some alternative embodiments, the conductive bar assembly may be formed as a unit type, and multiple conductive bar assemblies can be attached on a substrate strip. In that case, the substrate strip can later be singulated into multiple units of semiconductor devices, with each of them mounted with one or more conductive bar assemblies. In contrast, due to the needs of molding the bonding wires, the conventional semiconductor devices cannot be formed as singulated unit type packages and thus cannot be molded individually.

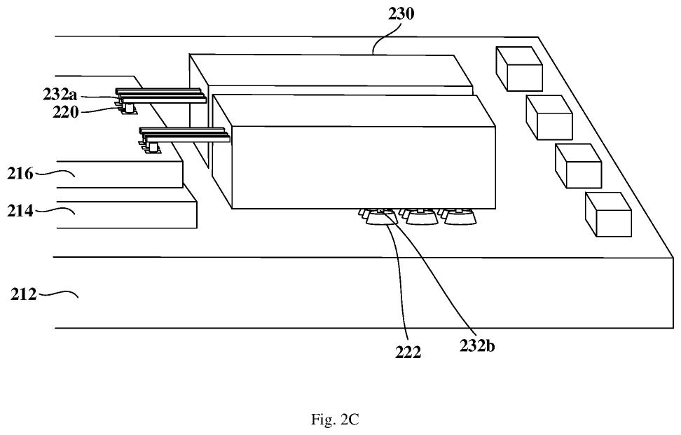

FIG. 3 illustrates an explosive view of an exemplary conductive bar assembly according to an embodiment of the present application.

As shown in FIG. 3, the conductive bar assembly includes an insulating body which has a base 330a and a cover 330b, and conductive bars 332. The base 330a is shaped as a cuboid which may have a size similar to but smaller than the entire conductive bar assembly. Multiple grooves 334 may be formed that extend between a top surface and a lateral surface of the base 330a, which can then be used for accommodating at least a portion of the conductive bars 332. The cover 330b is shaped as a cover plate having an L-shaped cross section, to fit for the cubic base 330a. Furthermore, the L-shaped cover 330b has multiple ridges 336 extending from its inner surface, which correspond to the grooves 334 of the base 330a, respectively. When the cover 330b is assembled with the base 330a, the ridges 336 of the cover 330b may be inserted within the respective grooves 334 of the base 330a, leaving only multiple L-shaped channels (see FIG. 2B) for accommodating the conductive bars, respectively. Also, the separated pairs of groove 334 and ridge 336 ensure electrical isolation between each two adjacent conductive bars 332.

The conductive bars 332 may include any number of conductive bars, depending on the number of bonding pads and conductive patterns to be interconnected by the conductive bars 332. The conductive bars 332 may be made of a conductive material such as a metal or alloy material. The conductive bars 332 may be preformed using a molding or stamping process, for example. In the example shown in FIG. 3, each conductive bar is L-shaped, with a horizontal portion 333a and a vertical portion 333b that are jointed together. Another end of the horizontal portion 333a serves as a first end 332a of the conductive bar 332, and another end of the vertical portion 333b serves as a second end 332b of the conductive bar 332. It can be appreciated that the multiple conductive bars 332 may be spaced apart from each other to avoid any potential short issues. In some preferred embodiments, certain insulating material may be coated or wrapped around the conductive bars 332 to improve electrical isolation. For example, the conductive bar assembly may include an insulating sheath (not shown) disposed around each of the conductive bars 332 to mechanically connect the conductive bars 332 together but electrically isolate them from each other. As such, it may be more convenient to assemble the conductive bars 332 with the insulating body, compared with conventional wire bonding processing. In addition, a pitch for the conductive bars of the conductive bar assembly, i.e., a distance between each two adjacent conductive bars, can be smaller since it can be preformed before being mounted to a substrate.

It can be appreciated that the embodiment shown in FIG. 3 is only an example for assembling the conductive bars inside the insulating body, and various alternative ways and structures may be utilized. For example, the conductive bars may be bonded together with an insulating sheath, and then may be placed within a mold chase. In that case, the insulating body may be formed from a molding material using a molding process.

Some modifications or changes may be made to the example shown in FIG. 3. For example, two or more sets of conductive bars may be sandwiched between the base and the cover in parallel as a strip type conductive bar assembly. The strip type conductive bar assembly may be singulated into multiple pieces or units of conductive bar assemblies, either before being mounted to a substrate of a semiconductor device or after being mounted to a substrate strip of semiconductor devices. In another example, the conductive bars may be distributed in two or more layers in the insulating body.

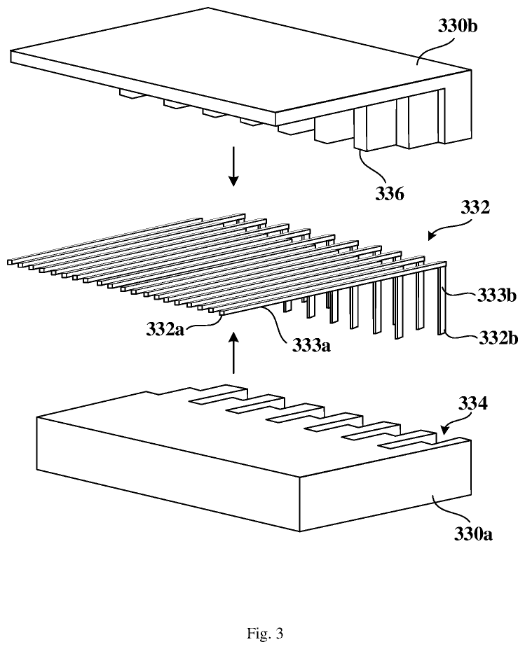

FIG. 4 illustrates a semiconductor device 400 according to an embodiment of the present application.

As shown in FIG. 4, the semiconductor device 400 includes a substrate 412 where two semiconductor dice 414 and 416 may be stacked together. The semiconductor die 414 may be a flip-chip type semiconductor die, which can be mounted onto a set of conductive patterns on the top surface of the substrate 412 via a set of conductive pillars or solder bumps 418. The upper semiconductor die 416 may be a wire bonding type semiconductor die, which has on its top surface a first set of bonding pads 420 and a second set of bonding pads 421 for interconnection purpose.

Other than the first set of conductive patterns which the semiconductor die 414 is connected to, the substrate 412 may have a second set of conductive patterns and a third set of conductive patterns. In particular, the second set of conductive patterns may be both disposed at a side of the stacked semiconductor dice 414 and 416. A conductive bar assembly 430 may be used to electrically connect the second set of conductive patterns with the first set of bonding pads 420 on top of the semiconductor die 416. Furthermore, another conductive bar assembly 440 may be used to electrically connect the third set of conductive patterns with the second set of bonding pads 421. As shown in FIG. 4, each of the conductive bar assemblies 430 and 440 may take the form of a z-shaped plate, with a portion lying above the semiconductor die 416 and another portion lying above the substrate 412 which are connected together by a sloping portion. Since the conductive bar assembly 430 is generally extending below the conductive bar assembly 440, conductive bars inside the conductive bar assembly 430 may not interfere with conductive bars inside the conductive bar assembly 440 in layout. Furthermore, the conductive bars of each of the conductive bar assemblies 430 and 440 may have two sets of ends which are both exposed from a bottom surface of the conductive bar assembly 430 or 440. For example, the conductive bars of the conductive bar assembly 430 has the set of ends 442 exposed from its bottom surface and connected to the second set of conductive patterns on the substrate 412 via solder bumps 422. Similarly, the conductive bars of the conductive bar assembly 440 has the set of ends 432 exposed from its bottom surface and connected to the third set of conductive patterns on the substrate 412 via solder bumps 424.

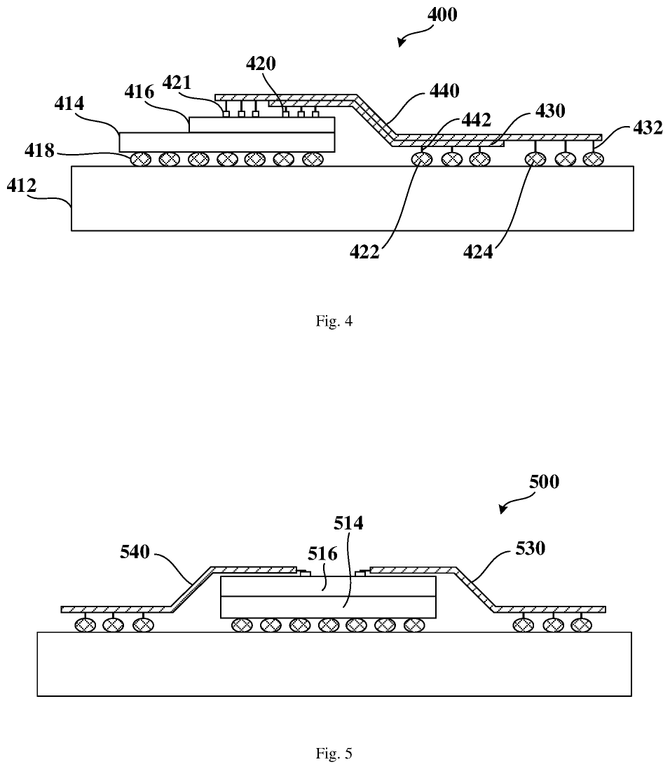

FIG. 5 illustrates a semiconductor device 500 according to an embodiment of the present application.

As shown in FIG. 5, different from the semiconductor device 400 shown in FIG. 4, the semiconductor device 500 includes two conductive bars assemblies 530 and 540 which are disposed two different sides of the stacked semiconductor dice 514 and 516. For example, the two conductive bars assemblies 530 and 540 may be disposed at two opposite sides of the stacked semiconductor dice 514 and 516.

Although it is described in the above embodiments that the semiconductor dices are stacked together on the substrate of a semiconductor device, in some other embodiments only one semiconductor die with bonding pads on its top surface may be mounted to the substrate, e.g. through solder bumps that can provide electrical connection, or through adhesive that cannot provide electrical connection.

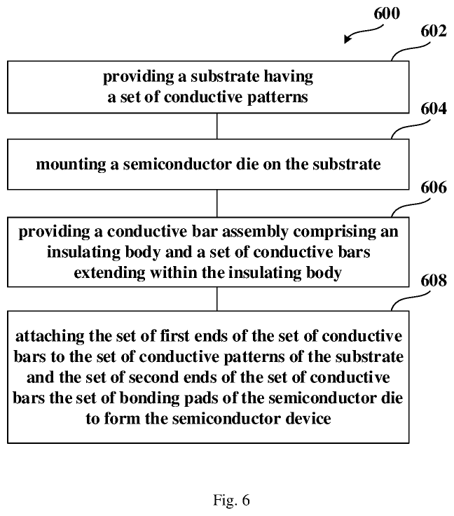

FIG. 6 illustrates a method 600 for forming a semiconductor device according to an embodiment of the present application. The method may be used to form the semiconductor devices 200, 400, or 500 shown in FIGS. 2A to 2C, FIG. 4 and FIG. 5, respectively.

As shown in FIG. 6, in step 602, a substrate having a set of conductive patterns is provided. In step 604, a semiconductor die is mounted on the substrate, wherein the semiconductor die has on its top surface a set of bonding pads. In step 606, a conductive bar assembly is provided, which comprises an insulating body and a set of conductive bars extending within the insulating body, wherein the set of conductive bars have a set of first ends exposed from a first surface of the insulating body and a set of second ends exposed from a second surface of the insulating body. In step 608, the set of first ends of the set of conductive bars are attached to the set of conductive patterns of the substrate, and the set of second ends of the set of conductive bars are attached to the set of bonding pads of the semiconductor die to form the semiconductor device.

In some embodiments, the semiconductor die is a first semiconductor die, and step 604 comprises: mounting a second semiconductor die mounted on the substrate; and attaching the first semiconductor die onto the second semiconductor die via adhesive.

In some embodiments, the method 600 further comprises singulating the semiconductor device into individual units.

In some embodiments, step 606 comprises: providing a base and a cover; inserting the set of conductive bars between the base and the cover; and attaching the base to the cover.

In some embodiments, before inserting the set of conductive bars between the base and the cover, step 606 further comprises: disposing an insulating sheath around each of the set of conductive bars to mechanically connect the set of conductive bars together but electrically isolate the set of conductive bars from each other.

While a semiconductor device and a method for forming a semiconductor device of the present application is described in conjunction with corresponding figures, it will be understood by those skilled in the art that modifications and adaptations to the device may be made without departing from the scope of the present invention.

The discussion herein included numerous illustrative figures that showed various portions of a semiconductor device and a method for forming a semiconductor device. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor device, comprising:
a substrate having a set of conductive patterns;
a semiconductor die mounted on the substrate, wherein the semiconductor die has on its top surface a set of bonding pads; and
a conductive bar assembly for electrically connecting the set of conductive patterns of the substrate with the set of bonding pads of the semiconductor die, wherein the conductive bar assembly comprises:
an insulating body; and
a set of conductive bars extending within the insulating body, wherein the set of conductive bars have a set of first ends exposed from a first surface of the insulating body to be electrically connected to the set of conductive patterns of the substrate and a set of second ends exposed from a second surface of the insulating body to be electrically connected to the set of bonding pads of the semiconductor die.

2. The semiconductor device of claim 1, wherein the second ends of the conductive bars are aligned with the set of bonding pads of the semiconductor die in a vertical direction of the substrate.

3. The semiconductor device of claim 1, wherein the conductive bar assembly is a preformed piece.

4. The semiconductor device of claim 1, wherein the insulating body comprises a base and a cover, and the set of conductive bars are disposed between the base and the cover.

5. The semiconductor device of claim 1, wherein the first surface is a bottom surface of the insulating body, and the second surface is a lateral surface of the insulating body.

6. The semiconductor device of claim 1, wherein the first surface is a bottom surface of the insulating body, and the second surface is a top surface of the insulating body.

7. The semiconductor device of claim 1, the first surface is a first lateral surface of the insulating body, and the second surface is a second lateral surface of the insulating body.

8. The semiconductor device of claim 1, wherein the conductive bar assembly further comprises:
an insulating sheath disposed around each of the set of conductive bars to mechanically connect the set of conductive bars together but electrically isolate the set of conductive bars from each other.

9. The semiconductor device of claim 1, wherein the semiconductor die is a first semiconductor die, and the semiconductor device further comprises:
a second semiconductor die mounted between the substrate and the first semiconductor die, wherein the second semiconductor die is attached onto another set of conductive patterns on the substrate, and the first semiconductor die is attached to the second semiconductor die via adhesive.

10. The semiconductor device of claim 9, wherein the second semiconductor die is a flip chip type semiconductor die.

11. The semiconductor device of claim 1, wherein the semiconductor device is a strip type semiconductor device.

12. The semiconductor device of claim 1, wherein the semiconductor device is a unit type semiconductor device.

13. The semiconductor device of claim 1, wherein the set of conductive patterns on the substrate is a first set of conductive patterns, the set of bonding pads on the top surface of the semiconductor die is a first set of bonding pads; the substrate comprises a second set of conductive patterns and the semiconductor die has on its top surface a second set of bonding pads; and wherein the semiconductor device further comprises:
a second conductive bar assembly for electrically connecting the second set of conductive patterns of the substrate with the second set of bonding pads of the semiconductor die, wherein the second conductive bar assembly comprises:
an insulating body; and
a set of conductive bars extending within the insulating body, wherein the set of conductive bars have a set of first ends exposed from a first surface of the insulating body to be electrically connected to the second set of conductive patterns of the substrate and a set of second ends exposed from a second surface of the insulating body to be electrically connected to the second set of bonding pads of the semiconductor die.

14. The semiconductor device of claim 13, wherein the conductive bar assembly and the second conductive bar assembly are disposed at two different sides of the semiconductor die.

15. The semiconductor device of claim 13, wherein the conductive bar assembly and the second conductive bar assembly are disposed at a same side of the semiconductor die.

16. The semiconductor device of claim 15, wherein the conductive bar assembly and the second conductive bar assembly at least partially overlap with each other.

17. The semiconductor device of claim 1, wherein the first surface and the second surface are a same surface of the insulating body.

18. A method for forming a semiconductor device, wherein the method comprises:
providing a substrate having a set of conductive patterns;
mounting a semiconductor die on the substrate, wherein the semiconductor die has on its top surface a set of bonding pads;
providing a conductive bar assembly comprising an insulating body and a set of conductive bars extending within the insulating body, wherein the set of conductive bars have a set of first ends exposed from a first surface of the insulating body and a set of second ends exposed from a second surface of the insulating body; and
attaching the set of first ends of the set of conductive bars to the set of conductive patterns of the substrate and the set of second ends of the set of conductive bars to the set of bonding pads of the semiconductor die to form the semiconductor device.

19. The method of claim 18, wherein the semiconductor die is a first semiconductor die, and wherein mounting the first semiconductor die on the substrate comprises:
mounting a second semiconductor die on the substrate; and
attaching the first semiconductor die onto the second semiconductor die via adhesive.

20. The method of claim 18, wherein providing a conductive bar assembly comprises:
providing a base and a cover;
inserting the set of conductive bars between the base and the cover; and
attaching the base to the cover.
